(19) United States
(12) Patent Application Publication
(10) Pub. No.: US 2025/0293650 A1
(43) Pub. Date: Sep. 18, 2025

(54) POWER AMPLIFIER SYSTEM

(71) Applicant: ETRA SEMICONDUCTOR (SUZHOU) CO., LTD., Suzhou (CN)

(72) Inventors: Xinyu LIU, Suzhou (CN); Yuanqing WANG, Suzhou (CN); Jun CHEN, Suzhou (CN)

(73) Assignee: ETRA SEMICONDUCTOR (SUZHOU) CO., LTD., Suzhou (CN)

(21) Appl. No.: 19/030,703

(22) Filed: Jan. 17, 2025

Related U.S. Application Data
(63) Continuation of application No. PCT/CN2024/128348, filed on Oct. 30, 2024.

(30) Foreign Application Priority Data
Mar. 12, 2024 (CN) 202410280782.2

(51) Int. Cl. H03F 3/60; H03F 1/56; H03F 3/24; H03F 3/45

(52) U.S. Cl. CPC H03F 3/602; H03F 1/56; H03F 3/245; H03F 3/45475; H03F 2203/21139

(57) ABSTRACT

The present disclosure provides a power amplifier system. The system includes: a differential power divider configured to perform power distribution on an input signal and output a plurality of sub-differential signals; a plurality of branch differential amplifying circuits, wherein each branch differential amplifying circuit of the plurality of branch differential amplifying circuits is configured to amplify a corresponding sub-differential signal; and a differential synthesizer connected with the plurality of branch differential amplifying circuits and configured to perform power synthesis on the plurality of sub-differential signals to obtain a synthesized differential signal; wherein an operating state of at least one of the plurality of branch differential amplifying circuits is different from that of the other branch differential amplifying circuits of the plurality of branch differential amplifying circuits.

### CROSS-REFERENCE TO RELATED APPLICATIONS

This application is a continuation of international application No. PCT/CN2024/128348, filed on Oct. 30, 2024, which claims priority to Chinese patent application No. 202410280782.2, filed on Mar. 12, 2024, the entire contents of each of which are incorporated herein by reference.

### TECHNICAL FIELD

This present disclosure relates to the field of radio frequency and microwave technology, and in particular, to a power amplifier system.

### BACKGROUND

Amplifiers are widely used in the field of wireless communications, and in order to achieve a high power output, a power synthesis network is often used to synthesize an output power of a plurality of amplifiers. For example, in base station communications and wireless LAN routing, a bandwidth, an efficiency, and a linearity of the amplifiers are key indicators.

During the development of modern communication systems, researchers have proposed a plurality of amplifier schemes. For example, the commonly used schemes are Doherty power synthesis, envelope elimination and recovery technology, and envelope tracking technology. Of these, the product structures of the envelope elimination and recovery technology and the envelope tracking technology are complex, requiring a use of complex digital systems. The Doherty power synthesis has a simple structure, while a plurality of power synthesis can be realized, but the Doherty power synthesis does not have characteristics of broadband. In the 21st century, the researchers proposed a Load-to-amplifier based on power combining network based on a balanced amplifier of K. KUROKAWA. For example, the paper “A load modulated balanced amplifier with linear gain response and wide high-efficiency output power back-off region,” presented by Kauser Chaudhry et al. in Proc. Int. Workshop Integr. Nonlinear Microw. Millimetre-Wave Circuits (INMMiC), pp. 1-3, July 2020, proposed a single-ended power combining amplifier structure, with a bandwidth of up to 1845 MHz and 2150 MHz, achieving an efficiency greater than 40% at a 6 dB saturation back-off.

The bandwidth of these amplifier structures is limited by their single-ended power combining amplifier structure, which are all in a vicinity of 25%, and do not satisfy broadband and high-efficiency needs of the modern communication systems.

Thus, the present disclosure provides a power amplifier system that enhances the efficiency of the power amplifier system during power back-off.

### SUMMARY

One or more embodiments of the present disclosure provide a power amplifier system comprising:
a differential power divider configured to perform power distribution on an input signal and output a plurality of sub-differential signals;
a plurality of branch differential amplifying circuits, wherein each branch differential amplifying circuit of the plurality of branch differential amplifying circuits is configured to amplify a corresponding sub-differential signal; and
a differential synthesizer connected with the plurality of branch differential amplifying circuits and configured to perform power synthesis on a plurality of amplified sub-differential signals to obtain a synthesized differential signal;
wherein an operating state of at least one of the plurality of branch differential amplifying circuits is different from that of the other branch differential amplifying circuits of the plurality of branch differential amplifying circuits.

In some embodiments, the at least one of the plurality of branch differential amplifying circuits includes: an impedance matching circuit and a power amplifying unit.

In some embodiments, the impedance matching circuit includes an input impedance matching circuit disposed on an input signal side of the power amplifying unit.

In some embodiments, the impedance matching circuit includes an output impedance matching circuit disposed on an output signal side of the power amplifying unit.

In some embodiments, the output impedance matching circuit includes an impedance adjusting unit, the impedance adjusting unit being configured to adjust an output impedance of the power amplifying unit of at least one branch differential amplifying circuit other than a branch differential amplifying circuit where the output impedance matching circuit is located.

In some embodiments, the impedance adjusting unit includes a switch, the switch being connected in parallel between a positive port and a negative port of a differential output port of the power amplifying unit on the branch differential amplifying circuit where the output impedance matching circuit is located.

In some embodiments, at least two of the plurality of branch differential amplifying circuits start operating when an output power is greater than a first threshold value and start operating when the output power is greater than a second threshold value, respectively, and the second threshold value is greater than the first threshold value.

In some embodiments, the operating state at which the output power is greater than the first threshold value is an operating state of a class A amplifier or an operating state of a class AB amplifier.

In some embodiments, the operating state at which the output power is greater than the second threshold value is an operating state of a class B amplifier or a class C amplifier.

In some embodiments, the differential synthesizer includes input ports of the plurality of sub-differential signals, an output port of the synthesized differential signal, and N pairs of differential coupling lines connected between the input ports of the plurality of sub-differential signals and the output port of the synthesized differential signal; a pair of a positive input port and a negative input port of at least one of the plurality of sub-differential signals is connected to a positive coupling line and a negative coupling line of different pairs of differential coupling lines in the N pairs of differential coupling lines, N≥2, and N is a positive integer.

In some embodiments, the input ports of the plurality of sub-differential signals of the differential synthesizer are not isolated from each other.

In some embodiments, the differential synthesizer includes input ports of the plurality of sub-differential signals, an output port of the synthesized differential signal, and N pairs of differential coupling lines connected between the input ports of the plurality of sub-differential signals and the output port of the synthesized differential signal; a pair of a positive input port and a negative input port of each of the plurality of sub-differential signals is connected to a pair of a positive coupling line and a negative coupling line of a corresponding pair of differential coupling lines in the N pairs of differential coupling lines, N≥2, and N is a positive integer.

In some embodiments, an isolation circuit is disposed between input ports of at least two sub-differential signals in the differential synthesizer.

### BRIEF DESCRIPTION OF THE DRAWINGS

The present disclosure is further described in terms of exemplary embodiments. These exemplary embodiments are described in detail with reference to the drawings. The drawings are not to scale. These embodiments are non-limiting exemplary embodiments, in which like reference numerals represent similar structures throughout the several views of the drawings, and wherein:

FIG. 1 is a schematic diagram of a power amplifier system according to some embodiments of the present disclosure;

FIG. 2 is a schematic diagram of a specific implementation of the power amplifier system according to some embodiments of the present disclosure;

FIG. 3 is a schematic diagram illustrating a structure of a differential power divider with broadband performance according to some embodiments of the present disclosure;

FIG. 4 is a schematic diagram of a specific example of the broadband differential power divider in FIG. 3 when N=2, according to some embodiments of the present disclosure;

FIG. 5 is a schematic diagram of a specific example of the broadband differential power divider in FIG. 3 when N=3, according to some embodiments of the present disclosure;

FIG. 6 is a schematic diagram illustrating a structure of another differential power divider with broadband performance according to some embodiments of the present disclosure;

FIG. 7 is a schematic diagram of a specific example of the broadband differential power divider in FIG. 6 when N=2, according to some embodiments of the present disclosure;

FIG. 8 is a schematic diagram of a specific example of the broadband differential power divider in FIG. 6 when N=3, according to some embodiments of the present disclosure;

FIG. 9 is a schematic diagram of a specific implementation of another power amplifier system provided in Embodiment 3 of the present disclosure;

FIG. 10 is a diagram of simulation results of the operating efficiency in Experimental Embodiment 1 according to some embodiments of the present disclosure;

FIG. 11 is a diagram of simulation results of the linear performance in Experimental Embodiment 1 according to some embodiments of the present disclosure;

FIG. 12 is a diagram of simulation results of the operating efficiency in Experimental Embodiment 2 according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system”, “device”, “unit” and/or “module” as used herein is a way to distinguish between different components, elements, parts, sections or assemblies at different levels. However, the words may be replaced by other expressions if other words accomplish the same purpose.

As shown in the present disclosure and in the claims, unless the context clearly suggests an exception, the words “one,” “a,” “an,” and/or “the” do not refer specifically to the singular, but may also include the plural. Generally, the terms “including” and “comprising” suggest only the inclusion of clearly identified steps and elements. In general, the terms “including” and “comprising” only suggest the inclusion of expressly identified steps and elements that do not constitute an exclusive list, and the method or apparatus may also include other steps or elements.

Flowcharts are used in the present disclosure to illustrate operations performed by a system according to embodiments of the present disclosure. It should be appreciated that the preceding or following operations are not necessarily performed in an exact sequence. Instead, steps can be processed in reverse order or simultaneously. Also, it is possible to add other operations to these processes or remove a step or steps from them.

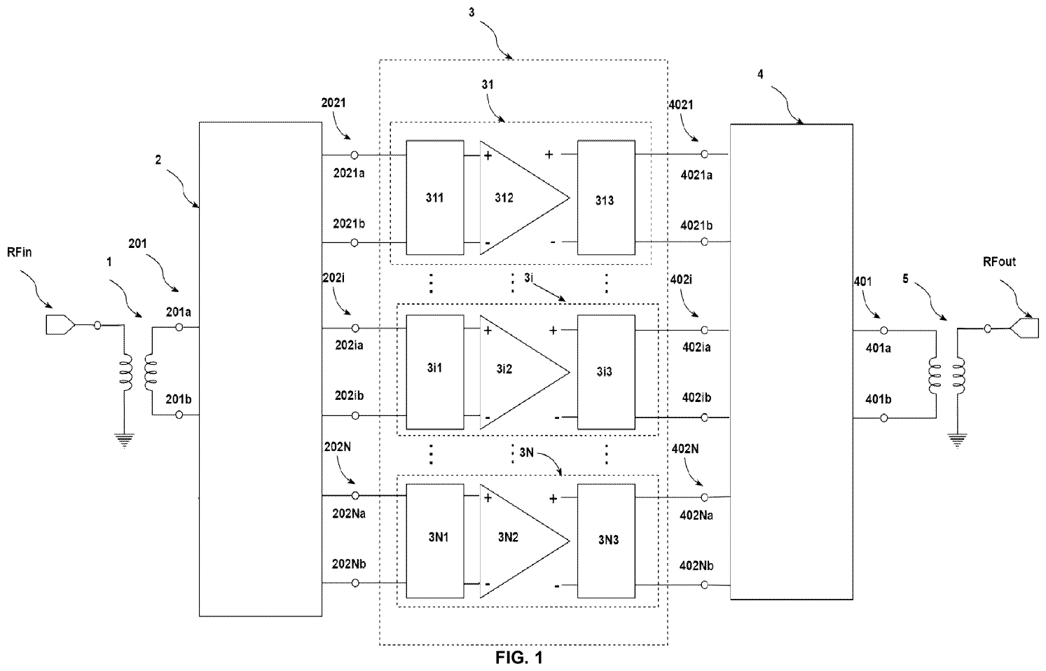

It is to be specified that a power amplifier system referred to in the following attached FIG. 1-FIG. 12 may also be referred to as a power amplifier system based on a differential power combining network, a differential amplifying circuit may also be referred to as a differential amplifying circuit module, a balun circuit may also be referred to as a balun, a branch differential amplifying circuit may be referred to as a branch differential amplifying circuit module, an impedance matching circuit may also be referred to an impedance matching circuit unit, an input impedance matching circuit may also be referred to an input impedance matching circuit unit, an output impedance matching circuit may also be referred to an output impedance matching circuit unit, and a isolation circuit may also be referred to an isolation module.

This present disclosure discloses the power amplifier system including a differential power divider, a plurality of branch differential amplifying circuits, and a differential synthesizer, the differential synthesizer being connected to the plurality of branch differential amplifying circuits.

The differential power divider is configured to perform power distribution on an input signal and output a plurality of sub-differential signals. The sub-differential signal is a pair of electrical signals with a same amplitude and an opposite phase.

Each branch differential amplifying circuit of the plurality of branch differential amplifying circuits is configured to amplify a corresponding sub-differential signal.

The differential synthesizer is configured to perform power synthesis on the plurality of amplified sub-differential signals to obtain a synthesized differential signal. The synthesized differential signal is an electrical signal obtained by performing power synthesis on the plurality of amplified sub-differential signals.

In some embodiments, an operating state of at least one of the plurality of branch differential amplifying circuits is different from that of the other branch differential amplifying circuits of the plurality of branch differential amplifying circuits.

The operating state may reflect an output power level of the branch differential amplifying circuits.

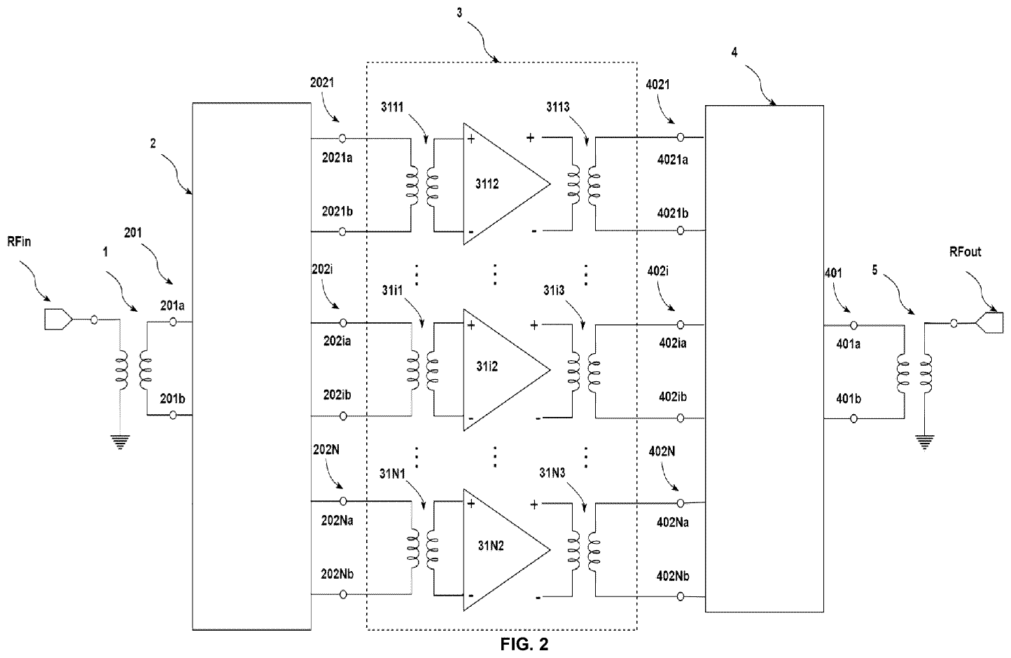

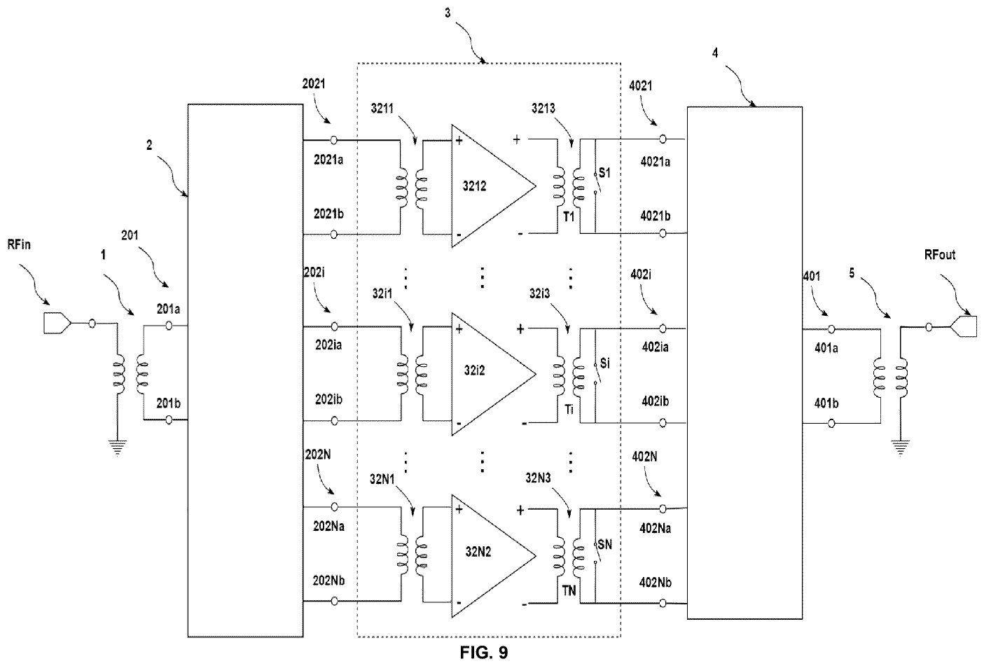

Merely by way of example, the power amplifier system may be one of power amplifier systems shown in FIG. 1 of embodiment 1, FIG. 2 of embodiment 2, and FIG. 9 of embodiment 3.

In some embodiments, the at least one of the branch differential amplifying circuits includes an impedance matching circuit and a power amplifying unit.

The power amplifying unit maybe configured to amplify the power of the plurality of sub-differential signals output by the differential power divider.

The impedance matching circuit is a circuit that acts as an impediment to current in the differential amplifying circuit. The impedance matching circuit may include at least one of a resistor, a capacitor, an inductor, etc.

In some embodiments, the impedance matching circuit includes an input impedance matching circuit disposed on an input signal side of the power amplifying unit.

The input impedance matching circuit refers to a circuit that acts as an impediment to the current of an input signal port of the power amplifying unit. For example, the input impedance matching circuit may be an input impedance matching circuit 31i1, etc., as shown in FIG. 2 of embodiment 2.

In some embodiments, the impedance matching circuit further includes an output impedance matching circuit disposed on an output signal side of the power amplifying unit.

The output impedance matching circuit refers to a circuit that acts as an impediment to the current of an output signal port of the power amplifying unit. For example, the output impedance matching circuit may be an output impedance matching circuit 31i3, etc., as shown in FIG. 2 of embodiment 2 below.

In some embodiments, the output impedance matching circuit includes an impedance adjusting unit. The impedance adjusting unit is configured to adjust an output impedance of the power amplifying unit of at least one branch differential amplifying circuit other than a branch differential amplifying circuit where the output impedance matching circuit is located.

In some embodiments, the impedance adjusting unit includes a switch, the switch being connected in parallel between a positive port and a negative port of a differential output port of the power amplifying unit on the branch differential amplifying circuit where the output impedance matching circuit is located. For example, the impedance adjusting unit, shown in FIG. 9 of embodiment 3, includes a switch S1, a switch Si, a switch SN, or the like.

In some embodiments, the differential synthesizer includes input ports of the plurality of sub-differential signals, an output port of the synthesized differential signal, and N pairs of differential coupling lines connected between the input ports of the plurality of sub-differential signals and the output port of the synthesized differential signal, N≥2, and N is a positive integer, wherein each pair of the N pairs of differential coupling lines include a positive coupling line and a negative coupling line. A pair of a positive input port and a negative input port of at least one of the plurality of sub-differential signals is connected to a positive coupling line and a negative coupling line of different pairs of differential coupling lines in the N pairs of differential coupling lines.

A pair of differential coupling lines refers to a signal transmission line including two paths that are coupled to each other, and are in parallel and equal in length. The differential coupling line can effectively offset external interference and noise to improve reliability of signal transmission and anti-jamming ability during the signal transmission process.

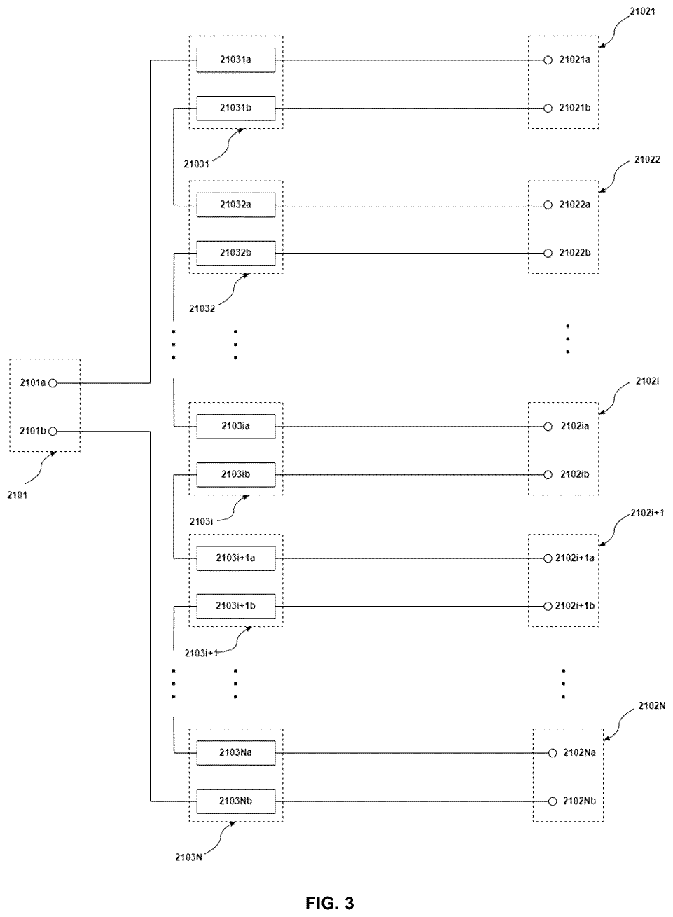

In some embodiments, a circuit structure of the differential synthesizer and a circuit structure of the differential power divider may be reversible. Merely by way of example, the differential synthesizer may be understood to be an inverse process of the differential power divider as shown in FIG. 3-FIG. 8 of embodiment 2.

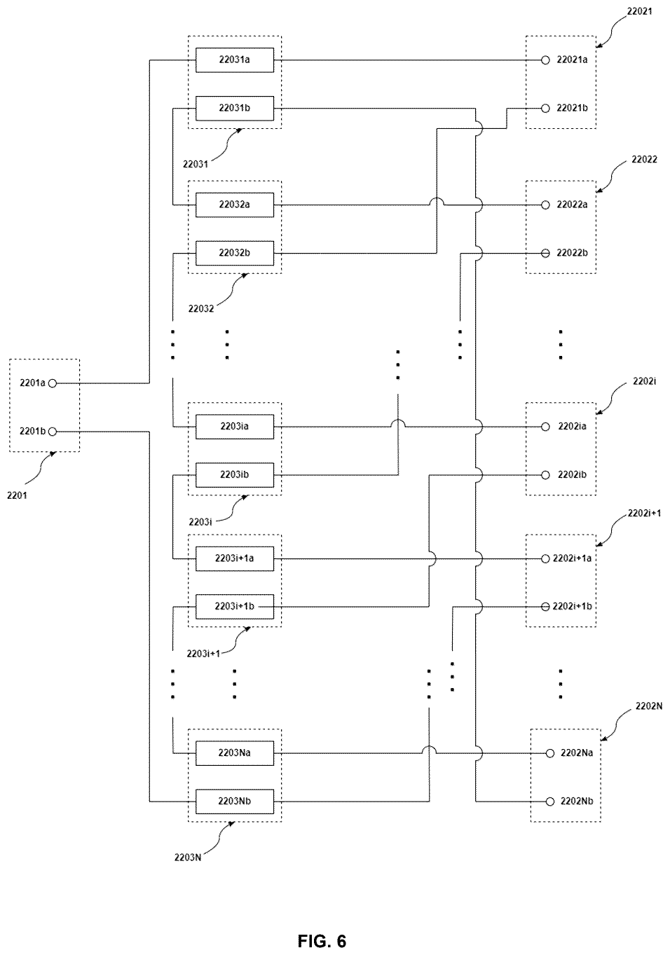

In some embodiments, the input ports of the plurality of sub-differential signals of the differential synthesizer are not isolated from each other. For example, there is no isolation between the output ports of the plurality of sub-differential signals of the differential power divider as shown in FIG. 3 and FIG. 6 of embodiment 2, and the differential synthesizer is a reverse process of the differential power divider as shown in FIG. 3 and FIG. 6 of embodiment 2, which is equivalent to no isolation between the input ports of the plurality of sub-differential signals of the differential synthesizer.

In some embodiments, at least two of the plurality of branch differential amplifying circuits start operating when an output power is greater than a first threshold value and start operating when the output power is greater than a second threshold value, respectively. The second threshold value is greater than the first threshold value. The first threshold value and the second threshold value may be predetermined for a person skilled in the art based on experience.

In some embodiments, the operating state at which the output power is greater than the first threshold value is an operating state of a class A amplifier or an operating state of a class AB amplifier.

The operating state of the class A amplifier refers to that the power amplifier is in a conduction state throughout an input signal cycle. The operating state of the class B amplifier refers to that the power amplifier is in a conduction state only during a positive half cycle or a negative half cycle of an input signal. The operating state of the class AB amplifier is between the operating state of the class A amplifier and the operating state of the class B amplifier.

In some embodiments, the operating state at which the output power is greater than the second threshold value is an operating state of the class B amplifier or a class C amplifier.

The operating state of the class C amplifier refers to that the power amplifier is in a conduction state during a preset period of the input signal, wherein the preset period is less than a half period of the input signal. The preset period may be preset empirically for a person skilled in the art.

In some embodiments, the differential synthesizer includes the input ports of the plurality of sub-differential signals, the output port of the synthesized differential signal, and the N pairs of differential coupling lines connected between the input ports of the plurality of sub-differential signals and the output port of the synthesized differential signal, N≥2, and N is a positive integer. A pair of the positive input port and the negative input port of each of the plurality of sub-differential signals is connected to the positive coupling line and the negative coupling line of a corresponding pair of differential coupling lines in the N pairs of differential coupling lines.

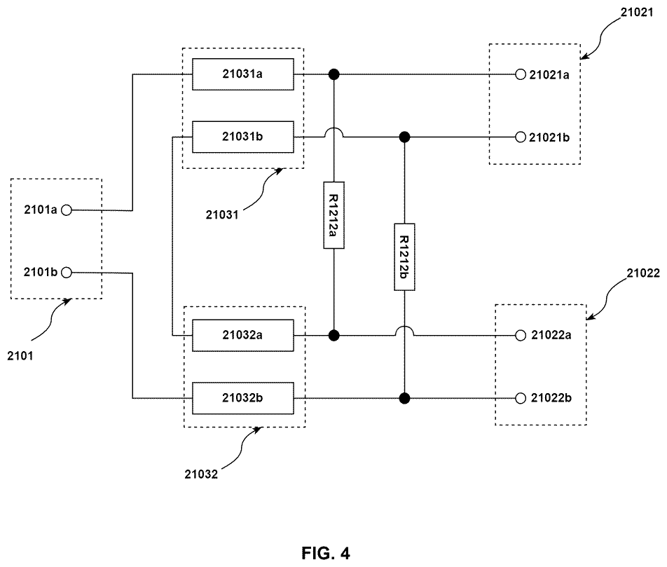

In some embodiments, an isolation circuit is disposed between the input ports of at least two sub-differential signals in the differential synthesizer. For example, the isolation circuit is provided between the output ports of the plurality of sub-differential signals of the differential power divider as shown in FIG. 4-5 and FIG. 7-8 of embodiment 2, and the differential synthesizer is a reverse process of the differential power divider as shown in FIG. 4-5 and FIG. 7-8 of embodiment 2, which is equivalent to providing an isolation circuit between the input ports of at least two sub-differential signals of the differential synthesizer.

The isolation circuit refers to a circuit that isolates ports with the same polarity in the output ports of the differential power dividers corresponding to different sub-differential signals.

In some embodiments, the isolation circuit may include an isolation resistor, or an isolation resistor and a capacitor that are connected in parallel. Merely by way of example, the power amplifier system may be one of the power amplifier systems as shown in FIG. 1 of embodiment 1, FIG. 2 of embodiment 2, FIG. 9 of embodiment 3, etc.

### Embodiment 1

FIG. 1 is a schematic diagram of a power amplifier system according to some embodiments of the present disclosure.

In some embodiments, the power amplifier system includes a differential power divider 2, a differential amplifying circuit 3, and a differential synthesizer 4, as shown in FIG. 1.

As shown in FIG. 1, if an original input signal is a single-ended input signal, an input balun circuit 1 maybe connected between a single-ended signal input port RFin and a differential signal input port 201 of the differential power divider 2. The input balun circuit 1 is configured to convert a single-ended signal into differential signals. The input balun circuit 1 couples the single-ended signal input port RFin to the differential signal input port 201 of the differential power divider 2. The input balun circuit 1 may be a balun circuit having a preset impedance ratio. The preset impedance ratio may be preset empirically for those skilled in the art. For example, the input balun circuit 1 may be a balun circuit with an impedance ratio of 1:1. The differential signal input port 201 includes a positive input port 201a and a negative input port 201b.

The single-ended input signal refers to an electrical signal including a reference port and a signal port, where the reference port is usually a grounding end.

As shown in FIG. 1, the differential power divider 2 receives a differential signal from the differential signal input 201 and perform power distribution on the differential signal to output a plurality of sub-differential signals. For example, the differential power divider 2 outputs N sub-differential signals, N≥2, and N is a positive integer. As shown in FIG. 1, the differential power divider 2 has N sub-differential signal output ports labeled as 2021-202N. Each sub-differential signal output port of the differential power divider 2 includes a positive output port and a negative output port. For example, the sub-differential output port 2021 includes a positive output port 2021a and a negative output port 2021b, and the sub-differential output port 202i includes a positive output port 202ia and a negative output port 202ib.

As shown in FIG. 1, each sub-differential signal of the plurality of sub-differential signals output by the differential power divider 2 is amplified by one branch differential amplifying circuit of the differential amplifying circuit 3, respectively, to obtain a plurality of amplified sub-differential signals. In FIG. 1, the differential amplifying circuit 3 includes a plurality of branch differential amplifying circuits that amplify each sub-differential signal of the plurality of sub-differential signals, which are labeled as 31-3N, respectively. An i-th branch differential amplifying circuit 3i amplifies an i-th sub-differential signal output by the differential power divider 2 to obtain an i-th amplified sub-differential signal, 1≤i≤N.

As shown in FIG. 1, the differential synthesizer 4 is connected to the differential amplifying circuit 3. The differential synthesizer 4 is configured to perform power synthesis on the plurality of sub-differential signals that are amplified by the differential amplifying circuit 3 to obtain a synthesized differential signal. In FIG. 1, the differential synthesizer 4 has N sub-differential signal input ports, labeled as 4021-402N, respectively. Each sub-differential signal input port has a positive input port and a negative input port. For example, the sub-differential signal input port 4021 includes a positive input port 4021a and a negative input port 4021b, the sub-differential signal input port 402i includes a positive input port 402ia and a negative input port 402ib, and the sub-differential signal input port 402N includes a positive input port 402Na and a negative input port 402Nb.

As shown in FIG. 1, each sub-differential signal input port of the differential synthesizer 4 is connected to an output port of a corresponding branch differential amplifying circuit, respectively. For example, in FIG. 1, the sub-differential signal input port 4021 of the differential synthesizer 4 is connected to the output port of the branch differential amplifying circuit 31, the sub-differential signal input port 402i of the differential synthesizer 4 is connected to the output port of the branch differential amplifying circuit 3i, and the sub-differential signal input port 402N of the differential synthesizer 4 is connected to the output port of the branch differential amplifying circuit 3N. The differential signals synthesized by the differential synthesizer 4 are output through the differential output port 401 of the differential synthesizer 4, and the differential output port 401 may include a positive output port 401a and a negative output port 401b.

In some embodiments, the power amplifier system may also be connected to an output baroclinic circuit 5 at the differential output port 401 of the differential synthesizer 4 to convert the differential output signal into a single-ended output signal and output the single-ended output signal through the single-ended signal output RFout.

In some embodiments, an operating state of at least one of the plurality of branch differential amplifying circuits is different from that of the other branch differential amplifying circuits of the plurality of branch differential amplifying circuits.

In some embodiments of the present disclosure, the power amplifier system can make the whole power amplifier system have a broadband characteristic through a design of branch differential amplifying circuits with different operating states and through adopting a working mode of the differential signals. Meanwhile, the power amplifier system can adjust whether each branch differential amplifying circuit is turned on or not based on the output power to improve the working efficiency of the entire power amplifier system when the power is returned.

In some embodiments, in order to optimize impedance matching in the branch differential amplifying circuit, the at least one of the plurality of branch differential amplifying circuits includes an impedance matching circuit and a power amplifying unit. The impedance matching circuit is configured to achieve impedance matching of the power amplifying unit. The impedance matching may include at least one of an input impedance matching circuit disposed on an input signal side of the power amplifying unit, and an output impedance matching circuit disposed on an output signal side of the power amplifying unit. The impedance matching circuit may thus include at least one of an input impedance matching circuit and an output impedance matching circuit.

In FIG. 1, an example is illustrated in which each of the branch differential amplifying circuits includes the impedance matching circuit and the power amplifying unit, and each of the impedance matching circuit includes the input impedance matching circuit and the output impedance matching circuit. For example, the branch differential amplifying circuit 31 includes an input impedance matching circuit 311, a power amplifying unit 312, and an output impedance matching circuit 313, wherein the input impedance matching circuit 311 and the output impedance matching circuit 313 are configured to match an input impedance and an output impedance of the power amplifying unit 312, respectively. The branch differential amplifying circuit 3i includes an input impedance matching circuit 3i1, a power amplifying unit 3i2, and an output impedance matching circuit 3i3, wherein the input impedance matching circuit 3i1 and the output impedance matching circuit 3i3 are configured to match an input impedance and an output impedance of the power amplifying unit 3i2, respectively. The branch differential amplifying circuit 3N includes an input impedance matching circuit 3N1, a power amplifying unit 3N2, and an output impedance matching circuit 3N3, wherein the input impedance matching circuit 3N1 and the output impedance matching circuit 3N3 are configured to match an input impedance and an output impedance of the power amplifying unit 3N2, respectively. wherein 1≤i≤N.

Each power amplifying unit includes a differential input port and a differential output port, the differential input port including a positive port and a negative port, and the differential output port including a positive port and a negative port. Each power amplifying unit amplifies the sub-differential signal input from the differential input port and outputs the amplified sub-differential signal through the differential output port.

In some embodiments, in the plurality of branch differential amplifying circuits having the impedance matching circuit, compositional structures of the impedance matching circuits of at least two of the branch differential amplifying circuits may be different. For example, the impedance matching circuits of a portion of the branch differential amplifying circuits include the input impedance matching circuits, the impedance matching circuits of a portion of the branch differential amplifying circuits include the output impedance matching circuits, and the impedance matching circuits of a portion of the branch differential amplifying circuits include the input impedance matching circuits and the output impedance matching circuits.

In some embodiments, at least two of the plurality of branch differential amplifying circuits start operating when an output power is greater than a first threshold value and start operating when the output power is greater than a second threshold value, respectively. The second threshold value is greater than the first threshold value. For example, a portion of the branch differential amplifying circuits start operating when the output power is greater than the first threshold value, that is, when the output power is greater than the lower first threshold value (e.g., greater than 0). A portion of the branch differential amplifying circuits start operating when the output power is greater than the second threshold value, that is when the output power is greater than the higher second threshold value (e.g., greater than a certain relatively high power threshold value).

The operating state at which the output power is greater than the first threshold value may be an operating state of a class A amplifier or an operating state of a class AB amplifier. The branch differential amplifying circuits operating in the operating state of a class A or class AB amplifier may provide high performance with small signals, such as high gain and high linearity.

The operating state at which the output power is greater than the second threshold value may be an operating state of a class B amplifier or a class C amplifier. When the output power rises to a higher threshold, the branch differential amplifying circuits in the operating states of the class B amplifier and the class C amplifier begin to work.

In some embodiments, the branch differential amplifying circuits are in the operating state of the class A amplifier or the class AB amplifier remain in operation. With increase of the output power of the whole power amplifier, the branch differential amplifying circuits in the operating state of the class B amplifier and the class C amplifier begin to work, so as to improve output efficiency of the power amplifier system. When the output power decreases, the branch differential amplifying circuits in the operating state of the class B amplifier and the class C amplifier may stop working, and the branch differential amplifying circuits in the operating state of the class A amplifier or the class AB amplifier may work alone. Through this mechanism, the whole power amplifier system can maintain high power during high power and power back-off process.

### Embodiment 2

FIG. 2 is a schematic diagram of a specific realization system of a power amplifier system according to some embodiments of the present disclosure.

As shown in FIG. 2, the power amplifier system includes the differential power divider 2, the differential amplifying circuit 3 including a plurality of branch differential amplifying circuits, and a differential combiner 4. The differential signal input port 201 of the differential power divider 2 includes the positive input port 201a and the negative input port 201b.

Based on the reason that the original input signal is a single-ended input signal, the input balun circuit 1 is connected between the single-ended signal input port RFin and the differential signal input port 201 of the differential power divider 2. The input balun circuit 1 is configured to convert a single-ended signal into a differential signal. The input balun circuit 1 couples the single-ended signal input port RFin to the differential signal input port 201 of the differential power divider 2. The input balun circuit 1 may be a balun circuit having a preset impedance ratio. The preset impedance ratio may be preset empirically for those skilled in the art. For example, the input balun circuit 1 may be a balun circuit with an impedance ratio of 1:1.

The differential power divider 2 is configured to perform power distribution on the differential signals from the differential signal input port 201 to obtain a plurality of sub-differential signals and output the plurality of sub-differential signals through the plurality of sub-differential signal output ports 2021-202N. Each sub-differential signal output port includes a positive output port and a negative output port. Each branch differential amplifying circuit is connected to a sub-differential signal output port corresponding to the differential power divider 2.

Each branch differential amplifying circuit includes an input impedance matching circuit, a power amplifying unit, and an output impedance matching circuit. For example, as shown in FIG. 2, the i-th branch differential amplifying circuit includes an input impedance matching circuit 31i1, a power amplifying unit 31i2, and an output impedance matching circuit 31i3, wherein 1≥i≥N. The input impedance matching circuit may be an impedance converter with a differential ratio of 1:1. For example, the input impedance matching circuit of each of the branch circuits may be an impedance converter with a differential ratio of 1:1. One of power amplifying units of the plurality of branches operates in the operating state of the class AB amplifier, and power amplifying units of other branches operate in the operating state of the class B amplifier. For example, the power amplifying unit 3112 of a first branch operates in the operating state of the class AB amplifier, and the power amplifying units 3122-31N2 of the other branches operate in the operating state of the class B amplifier. The output impedance matching circuit may be an impedance converter with a differential ratio of 1:1. For example, the output impedance matching circuit of each branch may be an impedance converter with a differential ratio of 1:1.

Each sub-differential signal input port of the differential synthesizer 4 is connected to an output port of a corresponding branch differential amplifying circuit, respectively. For example, in FIG. 2, the sub-differential signal input port 4021 of the differential synthesizer 4 is connected to an output impedance matching circuit 3113 of a first branch, and the sub-differential signal input port 402i of the differential synthesizer 4 is connected to an output impedance matching circuit 31i3 of an i-th branch, and the sub-differential signal input port 402N of the differential synthesizer 4 is connected to an output impedance matching circuit 31N3 of an N-th branch, wherein 1≤i≥N.

In some embodiments, the power amplifier system may also be connected to the output balun circuit 5 at the differential output port 401 of the differential synthesizer 4 to convert the differential output signal into a single-ended output signal and output the single-ended output signal through a single-ended signal output RFout. The output balun circuit 5 may be a balun circuit with an impedance ratio of 1:1. The differential output port 401 of the differential synthesizer 4 may include the positive output port 401a and the negative output port 401b.

In some embodiments, in order to further increase the bandwidth, the differential power divider 2 may utilize a differential power divider with broadband performance. The differential power dividers with broadband performance can maintain good performance over a wide frequency range.

FIG. 3 is a schematic diagram of a structure of a differential power divider with broadband performance according to some embodiments of the present disclosure.

As shown in FIG. 3, the differential power divider includes a differential signal input port 2101, N pairs of differential coupling lines 21031-2103N, and N sub-differential signal output ports 21021-2102N. A pair of differential coupling line include a positive coupling line and a negative coupling line. For example, the positive coupling line and the negative coupling line of the i-th pair of differential coupling line are labeled as 2103ia and 2103ib, respectively, wherein 1≤i≤N.

The N pairs of differential coupling lines 21031-2103N are connected between the differential signal input port 2101 and the N sub-differential signal output ports 21021-2102N, and the positive output port and the negative output port of each sub-differential signal output port are connected to a positive coupling line and a negative coupling line of a corresponding pair of differential coupling line in the N pairs of differential coupling lines.

The differential signal input port 2101 includes a positive input port 2101a and a negative input port 2101b. The positive input port 2101a is connected to the positive coupling line 21031a of a 1-st pair of differential coupling lines 21031, and the negative input port 2101b is connected to the negative coupling line 2103Nb of an N-th pair of differential coupling lines 2103N. The negative coupling line 2103ib of an i-th pair of differential coupling lines 2103i is connected to a positive coupling line 2103(i+1)a of an (i+1)-th pair of the differential coupling lines 2103(i+1), for example, in series, wherein 1≤i<N.

A positive output port 21021a and a negative output port 21021b of the sub-differential signal output port 21021 are connected to a positive coupling line 21031a and a negative coupling line 21031b of a first pair of differential coupling lines 21031, respectively. A positive output port 2102Na and a negative output port 2102Nb of the sub-differential signal output port 2102N are connected to a positive coupling line 2103N and a negative coupling line 2103Nb of an N-th pair of differential coupling lines 2103N, respectively. A positive output port 2102ia and a negative output port 2102ib of the sub-differential signal output port 2102i are connected to a positive coupling line 2103ia and a negative coupling line 2103ib of the i-th pair of differential coupling lines 2103i, respectively, wherein 1≤i≤N.

In some embodiments, isolation circuits (not shown in FIG. 3) are also provided between ports with the same polarity of the different sub-differential signal output ports for increasing isolation. For example, the isolation circuits are provided between the positive ports of the different differential signal output ports, and the isolation circuits are provided between the negative ports of the different sub-differential signal output ports. The isolation circuit may include an isolation resistor, or an isolation resistor and a capacitor that are connected in parallel.

The following examples of N=2 and N=3 are given to illustrate broadband differential power dividers in FIG. 3.

FIG. 4 is a specific example of a broadband differential power divider in FIG. 3 when N=2 according to some embodiments of the present disclosure. The broadband differential power divider is a one-point-two differential power divider. The broadband differential power divider includes the differential signal input port 2101, two pairs of differential coupling lines 21031 and 21032, and two sub-differential signal output ports 21021 and 21022.

The differential signal input port 2101 includes the positive input port 2101a and the negative input port 2101b. The positive input port 2101a is connected to the positive coupling line 21031a of the first pair of differential coupling lines 21031, and the negative input port 2101b is connected to the negative coupling line 21032b of the second pair of differential coupling lines 21032. The negative coupling line 21031b of the first pair of differential coupling lines 21031 is connected to the positive coupling line 21032a of the second pair of differential coupling lines 21032, for example, in series.

The positive output port 21021a and the negative output port 21021b of the sub-differential signal output port 21021 are connected to a pair of the positive coupling line 21031a and the negative coupling line 21031b of the first pair of differential coupling lines 21031, respectively. The positive output port 21022a and the negative output port 21022b of the sub-differential signal output port 21022 are connected to a pair of the positive coupling line 21032a and the negative coupling line 21032b of the second pair of differential coupling lines 21032, respectively.

In order to increase the isolation, an isolation resistor R1212a is provided between the positive output port 21021a of the sub-differential signal output port 21021 and the positive output port 21022a of the sub-differential signal output port 21022; and an isolation resistor R1212b is provided between the negative output port 21021b of the sub-differential signal output port 21021 and the negative output port 21022b of the sub-differential signal output port 21022.

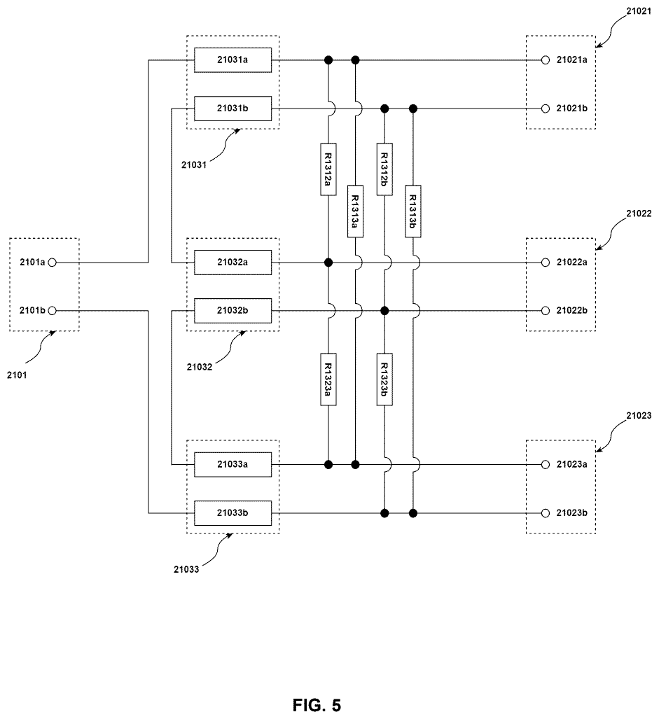

FIG. 5 is a schematic diagram of a specific example of the broadband differential power divider in FIG. 3 when N=3 according to some embodiments of the present disclosure. The broadband differential power divider is a one-point-three differential power divider. The broadband differential power divider includes the differential signal input port 2101, three pairs of differential coupling lines 21031-21033, and three sub-differential signal output ports 21021-21023.

The differential signal input port 2101 includes a positive input port 2101a and a negative input port 2101b. The positive input port 2101a is connected to the positive coupling line 21031a of the first pair of differential coupling lines 21031, and the negative input port 2101b is connected to the negative coupling line 21033b of the third pair of differential coupling lines 21033. The negative coupling line 21031b of the first pair of differential coupling lines 21031 is connected to the positive coupling line 21032a of the second pair of differential coupling lines 21032, for example, in series. The negative coupling line 21032b of the second pair of differential coupling lines 21032 is connected to the positive coupling line 21033a of the third pair of differential coupling lines 21033, for example, in series.

The positive output port 21021a and the negative output port 21021b of the sub-differential signal output port 21021 are connected to the positive coupling line 21031a and the negative coupling line 21031b of the first pair of differential coupling lines 21031, respectively. The positive output port 21022a and the negative output port 21022b of the sub-differential signal output port 21022 are connected to the positive coupling line 21032a and the negative coupling line 21032b of the second pair of differential coupling lines 21032, respectively. The positive output port 21023a and the negative output port 21023b of the sub-differential signal output port 21023 are connected to the positive coupling line 21033a and the negative coupling line 21033b of the third pair of differential coupling lines 21033, respectively.

In order to increase the isolation, an isolation resistor R1312a is provided between the positive output port 21021a of the sub-differential signal output port 21021 and the positive output port 21022a of the sub-differential signal output port 21022; and an isolation resistor R1312b is provided between the negative output port 21021b of the sub-differential signal output port 21021 and the negative output port 21022b of the sub-differential signal output port 21022. An isolation resistor R1313a is provided between the positive output port 21021a of the sub-differential signal output port 21021 and the positive output port 21023a of the sub-differential signal output port 21023; and an isolation resistor R1313b is provided between the negative output port 21021b of the sub-differential signal output port 21021 and the negative output port 21023b of the sub-differential signal output port 21023. An isolation resistor R1313a is provided between the positive output port 21021 of the sub-differential signal output port 21021 and the positive output port 21023a of the sub-differential signal output port 21023, and an isolation resistor R1313b is provided between the negative output port 21021b of the sub-differential signal output port 21021 and the negative output port 21023b of the sub-differential signal output port 21023.

In some embodiments, in order to further optimize isolation between the differential signal output ports of the differential power divider, the positive output port and the negative output port of at least one of the differential signal output ports may also be connected to the positive coupling lines and the negative coupling lines of different pairs of differential coupling lines.

FIG. 6 is a schematic diagram illustrating a structure of another differential power divider with broadband performance according to some embodiments of the present disclosure. As shown in FIG. 6, the broadband differential power divider includes a differential signal input port 2201, N pairs of differential coupling lines 22031-2203N, and N sub-differential signal output ports 22021-2202N. Each pair of differential coupling lines includes a positive coupling line and a negative coupling line. For example, a positive coupling line and a negative coupling line of the i-th pair of differential coupling lines are labeled as 2203ia and 2203ib, respectively, wherein 1≤i≤N.

The N pairs of differential coupling lines 22031-2203N are connected between the differential signal input port 2201 and the N sub-differential signal output ports 22021-2202N, and the positive output port and the negative output port of each sub-differential signal output port are connected to a positive coupling line and a negative coupling line of a corresponding pair of differential coupling lines.

The differential signal input port 2201 includes a positive input port 2201a and a negative input port 2201b. The positive input port 2201a is connected to the positive coupling line 22031a of the first pair of differential coupling lines 22031, and the negative input port 2201b is connected to the negative coupling line 2203Nb of the N-th pair of differential coupling lines 2203N. The negative coupling line 2203ib of the i-th pair of differential coupling lines 2203i is connected to the positive coupling line 2203(i+1)a of the (i+1) th pair of differential coupling lines, for example, in series, wherein 1≤i<N.

The positive output port 22021a and the negative output port 22021b of the sub-differential signal output port 22021 are connected to the positive coupling line 22031a of the first pair of differential coupling lines 22031 and the negative coupling line 22032b of the second pair of differential coupling lines 22032. According to some embodiments of the present disclosure, the positive output port 2202ia and the negative output port 2202ib of the sub-differential signal output port 2202i are connected to the positive coupling line 2203i of the i-th pair of differential coupling lines 2203i and the negative coupling line (2203i+1b) of the (i+1)-th pair of differential coupling lines, respectively, wherein 1≤i<N. The positive output port 2202Na and the negative output port 2202Nb of the sub-differential signal output port 2202N are connected to the positive coupling line 2203N of the N-th pair of differential coupling lines 2203N and the negative coupling line 22031b of the first pair of differential coupling lines 22031, respectively.

In some embodiments, isolation circuits (not shown in FIG. 3) may also be provided between the ports with the same polarity of different sub-differential signal output ports. For example, isolation circuits are provided between the positive ports of different sub-differential signal output ports and isolation circuits are provided between the negative ports of different sub-differential signal output ports. The isolation circuit may include an isolation resistor, or an isolation resistor and a capacitor that are connected in parallel.

It will be appreciated that the specific circuit structure implementation, as shown in FIG. 6 above, is only a specific example of realizing that the positive output port and the negative output port of the at least one of sub-differential signal output ports are connected to the positive coupling line and the negative coupling line of at least one of pairs of different differential coupling lines. In this example, the positive output port and the negative output port of each of the sub-differential signal output ports are connected to a positive coupling line and a negative coupling line of different pairs of differential coupling lines. In some embodiments, it is also possible that only a portion of the positive output ports and negative output ports of the sub-differential signal output ports are connected to positive coupling lines and negative coupling lines of the different pairs of differential coupling lines. In addition, even if the positive output port and the negative output port of each of the sub-differential signal output ports are connected to the positive coupling line and the negative coupling line of different pairs of differential coupling lines, but there are many ways to connect the sub-differential signal output ports to different pairs of differential coupling lines, and the ways are not limited to the cross-connections as shown in FIG. 6.

The following examples of N=2 and N=3 are given to illustrate the broadband differential power dividers in FIG. 6.

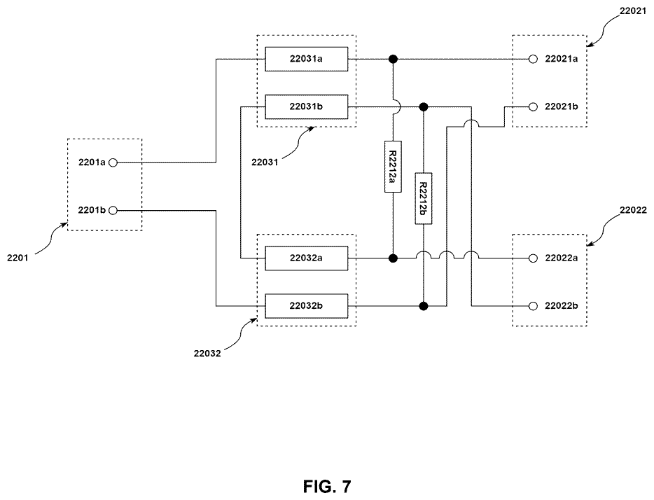

FIG. 7 shows a specific example of the broadband differential power divider in FIG. 6 when N=2. The broadband differential power divider is a one-point-two differential power divider, as shown in FIG. 7. The broadband differential power divider includes the differential signal input port 2201, two pairs of differential coupling lines 22031 and 22032, and two sub-differential signal output ports 22021 and 22022.

The differential signal input port 2201 includes the positive input port 2201a and the negative input port 2201b. The positive input port 2201a is connected to the positive coupling line 22031a of the first pair of differential coupling lines 22031, and the negative input port 2201b is connected to the negative coupling line 22032b of the second pair of differential coupling lines 22032. The negative coupling line 22031b of the first pair of differential coupling lines 22031 is connected to the positive coupling line 22032a of the second pair of differential coupling lines 22032, for example, in series.

The positive output port 22021a and the negative output port 22021b of the sub-differential signal output port 22021 are connected to the positive coupling line 22031a of the first pair of differential coupling lines 22031 and the negative coupling line 22032b of the second pair of differential coupling lines 22032, respectively. The positive output port 22022a and the negative output port 22022b of the sub-differential signal output port 22022 are connected to the positive coupling line 22032a of the second pair of differential coupling lines 22032 and the negative coupling line 22031b of the first pair of differential coupling lines 22031, respectively.

In order to increase the isolation, an isolation resistor R2212a is provided between the positive output port 22021a of the sub-differential signal output port 22021 and the positive output port 22022a of the sub-differential signal output port 22022, and an isolation resistor R2212b is provided between the negative output port 22021b of the sub-differential signal output port 22021 and the negative output port 22022b of the sub-differential signal output port 22022.

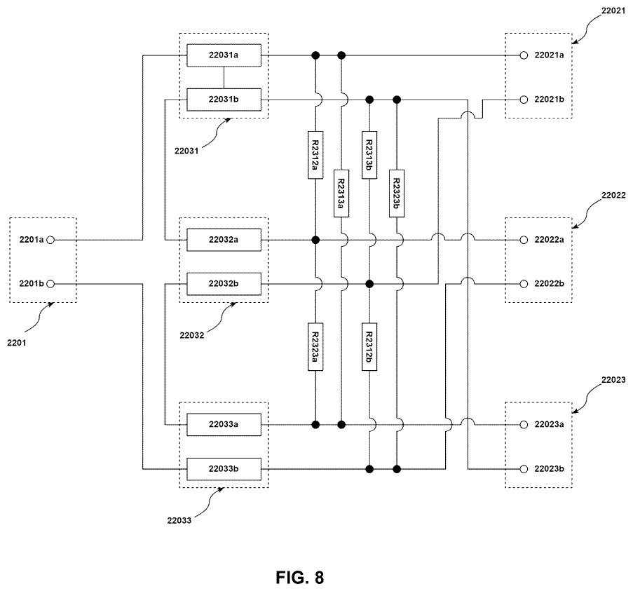

FIG. 8 illustrates a specific example of the broadband differential power divider in FIG. 6 when N=3 according to some embodiments of the present disclosure. As shown in FIG. 8, the broadband differential power divider is a one-point-three differential power divider comprising the differential signal input port 2201, three pairs of differential coupling lines 22031-22033, and three sub-differential signal output ports 22021-22023.

The differential signal input port 2201 includes the positive input port 2201a and the negative input port 2201b. The positive input port 2201a is connected to the positive coupling line 22031a of the first pair of differential coupling lines 22031, and the negative input port 2201b is connected to the negative coupling line 22033b of the third pair of differential coupling lines 22033, respectively. The negative coupling line 22031b of the first pair of differential coupling lines 22031 is connected to the positive coupling line 22032a of the second pair of differential coupling lines 22032, for example, in series. The negative coupling line 22032b of the second pair of differential coupling lines 22032 is connected to the positive coupling line 22033a of the third pair of differential coupling lines 22033, e.g., in series.

The positive output port 22021a and the negative output port 22021b of the sub-differential signal output port 22021 are connected to the positive coupling line 22031a of the first pair of differential coupling lines 22031 and the negative coupling line 22032b of the second pair of differential coupling lines 22032, respectively. The positive output port 22022a and the negative output port 22022b of the sub-differential signal output port 22022 are connected to the positive coupling line 22032a of the second pair of differential coupling lines 22032 and the negative coupling line 22033b of the third pair of differential coupling lines 22033, respectively. The positive output port 22023a and the negative output port 22023b of the sub-differential signal output port 22023 are connected to the positive coupling line 22033a of the third pair of differential coupling lines 22033 and the negative coupling line 22031b of the first pair of differential coupling lines 22031, respectively.

In order to increase the isolation, an isolation resistor R2312a is set between the positive output port 22021a of the sub-differential signal output port 22021 and the positive output port 22022a of the sub-differential signal output port 22022, and an isolation resistor R2312b is set between the negative output port 22021b of the sub-differential signal output port 22021 and the negative output port 22022b of the sub-differential signal output port 22022. An isolation resistor R2313a is set between the positive output port 22021a of the sub-differential signal output port 22021 and the positive output port 22023a of the sub-differential signal output port 22023, and an isolation resistor R2313b is set between the negative output port 22021b of the sub-differential signal output port 22021 and the negative output port 22023b of the sub-differential signal output port 22023. An isolation resistor R2313a is set between the positive output port 22021a of the sub-differential signal output port 22021 and the positive output port 22023a of the sub-differential signal output port 22023; and an isolation resistor R2313b is set between the negative output port 22021b of the sub-differential signal output port 22021 and the negative output port 22023b of the sub-differential signal output port 22023.

Because the circuit structures of the differential power divider and the differential synthesizer are reversible, the entire circuit structure of the differential power divider can still be applied to the differential synthesizer by simply using the plurality of differential signal output ports in the two types of broadband differential power divider illustrated in FIG. 3 and FIG. 6 as a plurality of sub-differential signal input ports of the differential synthesizer, and using the differential signal input ports in the two types of broadband differential power dividers shown in FIG. 3 and FIG. 6 as the sub-differential signal output ports of the differential synthesizer.

The circuit structures of the differential power divider and the differential synthesizer may be chosen to be different in the overall power amplifier system. For example, the differential power divider 2 selects the differential power divider structure as illustrated in FIG. 3, and the differential synthesizer 4 selects the inverse operation mode (i.e., a differential synthesizer mode of operation) of the differential power divider structure as shown in FIG. 6.

The circuit structures of the differential power divider and the differential synthesizer may be chosen to be essentially the same in the overall power amplifier system. For example, the differential power divider 2 selects the differential power divider structure as shown in FIG. 3, and the differential synthesizer 4 selects the inverse operation mode (i.e., a differential synthesizer mode of operation) of the differential power divider structure as shown in FIG. 3. Alternatively, the differential power divider 2 selects the differential power divider structure as shown in FIG. 6, and the differential synthesizer 4 selects the inverse operation mode (i.e., a differential synthesizer mode of operation) of the differential power divider structure as shown in FIG. 6.

### Embodiment 3

FIG. 9 is a schematic diagram of a specific implementation system of another power amplifier system according to Embodiment 3 of the present disclosure. The difference between the power amplifier system of FIG. 9 and the power amplifier system of Embodiment 2 is mainly that an impedance adjusting unit is added to the output impedance matching circuit in at least one of the branch differential amplifying circuits.

As shown in FIG. 9, the power amplifier system includes a differential power divider 2, a differential amplifying circuit 3 including a plurality of branch differential amplifying circuits, and a differential synthesizer 4. The differential signal input port 201 of the differential power divider 2 includes a positive input port 201a and a negative input port 201b.

Based on a reason that the original input signal is a single-ended input signal, an input balun circuit 1 is connected between the single-ended signal input port RFin and the differential signal input port 201 of the differential power divider 2. The input balun circuit 1 is configured to convert a single-ended signal into differential signals. The input balun circuit 1 couples the single-ended signal input port RFin to the differential signal input port 201 of the differential power divider 2. The input balun circuit 1 may be a balun circuit with a preset impedance ratio. The preset impedance ratio may be preset empirically for those skilled in the art. For example, the input balun circuit 1 may be a balun circuit with an impedance ratio of 1:1.

The differential power divider 2 is configured to perform differential power distribution on differential signals of the differential signal input port 201 to obtain a plurality of differential signals and output the plurality of differential signals through the plurality of sub-differential signal output ports 2021-202N. One sub-differential signal output port includes a positive output port and a negative output port. Each of the branch differential amplifying circuits is connected to one sub-differential signal output port corresponding to the differential power divider 2.

Each of the branch differential amplifying circuits includes an input impedance matching circuit, a power amplifying unit, and an output impedance matching circuit. For example, the i-th branch differential amplifying circuit includes an input impedance matching circuit 32i1, a power amplifying unit 32i2, and an output impedance matching circuit 32i3, wherein 1≤i≤N.

The power amplifying unit of one branch differential amplifying circuit operates in the operating state of the class AB amplifier, and the power amplifying units of the other branch differential amplifying circuits operate in the operating state of the class B amplifier. For example, the power amplifying unit 3212 of the first branch differential amplifying circuit operates in the operating state of the class AB amplifier, and the power amplifying units 3222-32N2 of the other branch differential amplifying circuits operate in the operating state of the class B amplifier. The output impedance matching circuit may be an impedance converter with a preset differential ratio. The impedance converter with the preset differential ratio may be preset empirically for those skilled in the art. For example, the output impedance matching circuit may be an impedance converter with a differential ratio of 1:1 or 1:4. For example, the output impedance matching circuit of the branch differential amplifying circuit in which the power amplifying unit operates in the operating state of the class AB amplifier may be an impedance converter with a differential ratio of 1:1, and the output impedance matching circuit of the branch differential amplifying circuit in which the power amplifying unit operates in the operating state of the class B amplifier may be an impedance converter with a differential ratio of 1:1 or 1:4.

In some embodiments of the present disclosure, the output impedance matching circuit of at least one branch includes an output impedance converter and an impedance adjusting unit. The impedance adjusting unit is configured to adjust the output impedance of a power amplifying unit of at least one branch other than the one branch in which the impedance adjusting unit is located.

In FIG. 9, the output impedance matching circuit of each of the branch circuits including the output impedance converter and the impedance adjusting unit is shown as an example. The output impedance matching circuit 32i3 of the i-th branch differential amplifying circuit includes an output impedance converter Ti and an impedance adjusting unit Si, and 1≤i≤N. The impedance adjusting unit includes a switch, the switch being connected in parallel between a positive port and a negative port of a differential output port of the power amplifying unit on a same branch differential amplifying circuit as the output impedance matching circuit.

In this embodiment, the differential synthesizer 4 may operate in an inverse operation mode (i.e., a differential synthesizer mode of operation) of the broadband differential power divider structure as shown in FIG. 6. And the differential synthesizer 4 is not provided with isolation circuits between the ports with the same polarity of the plurality of sub-differential signal input ports. The differential synthesizer makes it possible for the different differential signal input ports to interact with each other, and thus, through the setting of an impedance adjusting unit on one branch, it is possible to adjust the output impedance of the power amplifying unit in other branches.

Taking the switch of the impedance adjusting unit in FIG. 9 as an example, when the switch Si, which is the impedance adjusting unit of the i-th branch differential amplifying circuit, is closed, the two ports of the switch Si are short-circuited, and the power amplifying unit 32i2 of the i-th branch cannot output power externally. Because there is no isolation between the various sub-differential signal input ports of the differential synthesizer 4, the impedance of the ports corresponding to the other branches that are not shorted will be elevated, resulting in an increase in the load impedance of the power amplifying units of these branches and a decrease in saturation power. The higher the output power, the higher the efficiency of the power amplifying unit before it saturates. So under the same output power condition, the increase of load impedance will improve the efficiency. In summary, by closing the switch, the saturation power can be reduced to improve the efficiency of the entire power amplifier system at low output power.

According to some embodiments of the present disclosure, Embodiment 1, Embodiment 2, and Embodiment 3 are merely exemplary and do not constitute a limitation of this specification. While not expressly stated herein, a person skilled in the art may make various modifications, improvements, and amendments to this specification. Those types of modifications, improvements, and amendments are suggested in this specification, so those types of modifications, improvements, and amendments remain within the spirit and scope of the exemplary embodiments of this specification.

Specific experimental examples are set forth below to illustrate the technical effects of employing the power amplifier system in the embodiments of this specification.

### Experiment Example 1

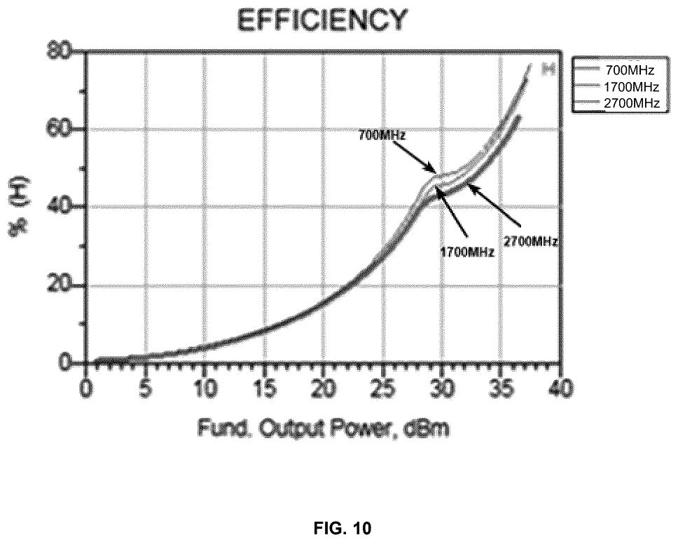

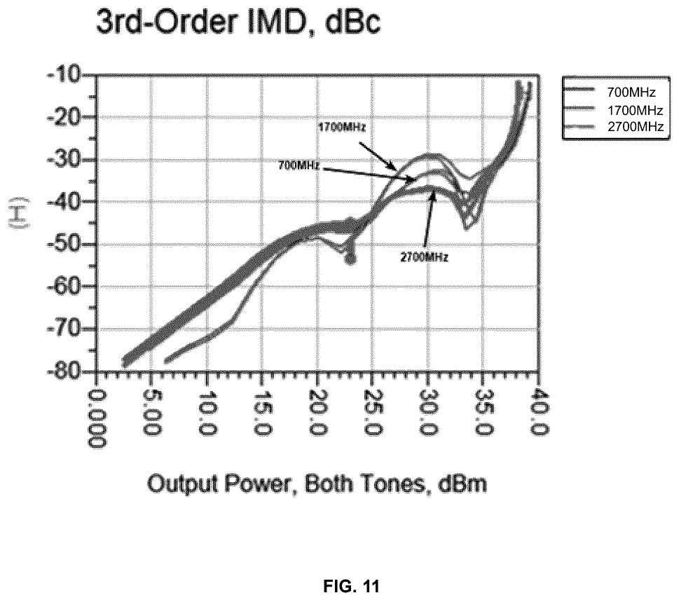

FIG. 10 is a diagram of simulation results of operating efficiency in Experimental Embodiment 1 according to some embodiments of the present disclosure. FIG. 11 is a diagram of simulation results of the linear performance in Experimental Embodiment 1 according to some embodiments of the present disclosure.

The power amplifier system in Experimental Example 1 adopts the structure of the power amplifier system provided by FIG. 2 of Embodiment 2 above, and a count of branches is selected to be 2, i.e., N=2. The differential power divider 2 is selected as a 1-in-2 differential power divider and the differential synthesizer 4 is selected as a 2-in-1 differential synthesizer. Therefore, the count of branches is 2, the two branch differential amplifying circuits operate in the operating state of the class AB amplifier and the operating state of the class B amplifier respectively, and the input balun circuit 1 and the output balun circuit 5 are both utilized with a balun circuit with an impedance ratio of 1:1. The horizontal coordinate of FIG. 10 represents the output power of the power amplifier system, and the vertical coordinate represents the operating efficiency of the power amplifier system. FIG. 10 shows a diagram of the simulation results of operating efficiency of the power amplifier system, and it can be seen that in the frequency range of 700 MHz-2700 MHz, the efficiency of the saturation regression of 6 dB is greater than 40%, that is, the operating bandwidth is greater than 55%. The horizontal coordinate of FIG. 11 represents the output power of the power amplifier system, and the vertical coordinate represents the magnitude of the third-order intermodulation rejection of the power amplifier system. The linear performance simulation results are shown in FIG. 11, and the third-order intermodulation rejection is greater than 30 dBc in the frequency range of 700 MHz-2700 MHz, which means that the linear operating bandwidth is greater than 55%.

### Experiment Embodiment 2

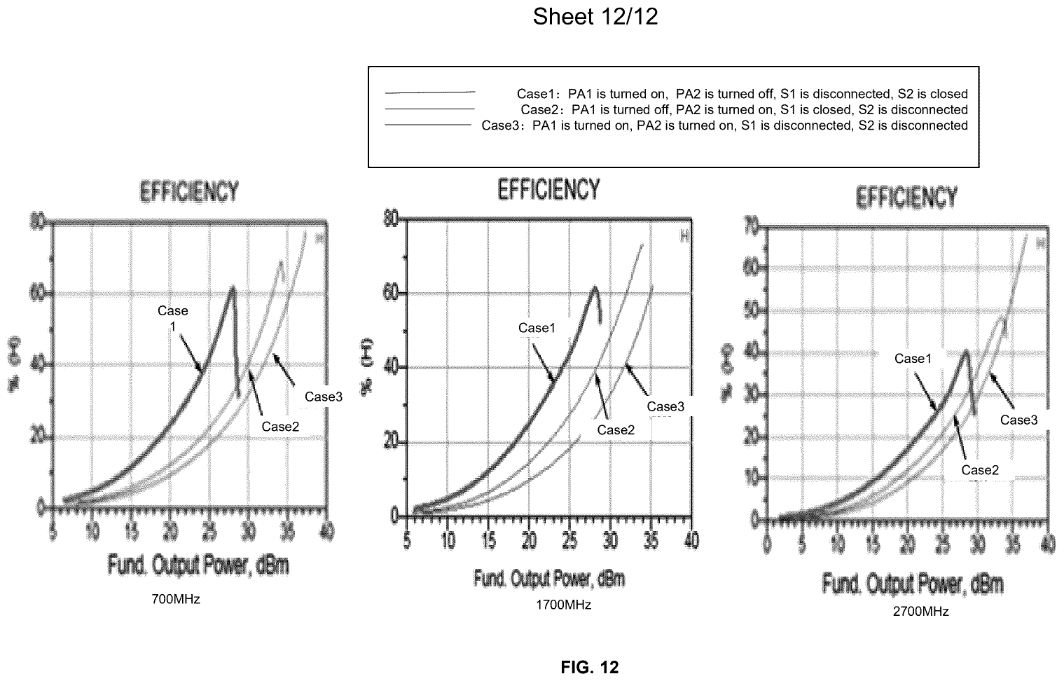

FIG. 12 is a diagram of simulation results of operating efficiency in Experimental Embodiment 2 according to some embodiments of the present disclosure. The horizontal coordinate of FIG. 12 represents the output power of the power amplifier system, and the vertical coordinate represents the operating efficiency of the power amplifier system.

The power amplifier system in Experimental Embodiment 2 adopts the structure of the power amplifier system provided by FIG. 9 in Embodiment 3 above, and the count of branch circuits is selected to be 2, i.e., N=2. The differential power divider 2 is selected as a 1-part-2 differential power divider and the differential synthesizer 4 is selected as a 2-in-1 differential synthesizer. The differential power divider 2 and differential synthesizer 4 select the 1-part-2 differential power divider structure of FIG. 7 and a inverse operation mode (i.e., the mode of operation of the differential synthesizer) of the 1-part-2 differential power divider structure of FIG. 7, respectively. There is no isolation circuit in the differential power divider 2 and the differential synthesizer 4, i.e., removing the two isolation resistors R2212a and R2212b in FIG. 7. The power amplifier system is simulated by experiments according to the following three cases respectively, and the simulated results are as shown in FIG. 12.

Case 1: the power amplifying unit 3212 (i.e., corresponding to the marking PA1 in FIG. 12) in the first branch is turned on, the power amplifying unit 3222 (i.e., corresponding to the marking PA2 in FIG. 12) in the second branch is turned off, the switch S1 in the first branch is disconnected, and the switch S2 in the second branch is closed.

Case 2: the power amplifying unit 3212 in the first branch is turned off, the power amplifying unit 3222 in the second branch is turned on, the switch S1 in the first branch is closed, and the switch S2 in the second branch is disconnected.

Case 3: the power amplifying unit 3212 in the first branch is turned on, the power amplifying unit 3222 in the second branch is turned on, the switch S1 in the first branch is disconnected, and the switch S2 in the second branch is disconnected.

The power amplifying unit 3212 operates in the operating state of the class AB amplifier, and the power amplifying unit 3222 operates in the operating state of the class B amplifier.

Referring to FIG. 12, it can be seen that the efficiency of the whole power amplifier system is greater than 40%, i.e., the operating bandwidth is greater than 55%, in the frequency range of 700 MHz-2700 MHz, with a saturation back-off of 10 dB.

Each of the embodiments in the present disclosure is described in a progressive manner, the same and similar parts of each of the embodiments can be referred to each other, and each of the embodiments highlights the differences from other implementation cases. In particular, for the system or system embodiments, the descriptions are simpler due to the fact that they are substantially similar to the method embodiments, and it is sufficient to refer to portions of the method embodiments as relevant. The systems and system embodiments described above are merely illustrative, wherein the units described as separate components illustrated may or may not be physically separate, and the components displayed as units may or may not be physical units, i.e., the units may be located in one place or may also be distributed to a plurality of network units. Some or all of these modules can be selected to fulfill the purpose of the embodiment scheme according to actual needs. One of ordinary skill in the art can understand and implement without creative labor.

The above technical solutions provided in the present disclosure are described in detail, and specific examples are applied herein to illustrate the principles and implementations of the present disclosure, and the illustrations of the above embodiments are only configured to aid in the understanding of the methods of the present disclosure and core ideas; at the same time, for those skilled in the art, according to the idea of the present disclosure, specific implementation methods and application scopes may be changed. In summary, the contents of this specification should not be construed as a limitation of the present disclosure.

What is claimed is:

1. A power amplifier system, comprising:
a differential power divider configured to perform power distribution on an input signal and output a plurality of sub-differential signals;
a plurality of branch differential amplifying circuits, wherein each branch differential amplifying circuit of the plurality of branch differential amplifying circuits is configured to amplify a corresponding sub-differential signal; and
a differential synthesizer connected with the plurality of branch differential amplifying circuits and configured to perform power synthesis on a plurality of amplified sub-differential signals to obtain a synthesized differential signal;
wherein an operating state of at least one of the plurality of branch differential amplifying circuits is different from that of the other branch differential amplifying circuits of the plurality of branch differential amplifying circuits.

2. The power amplifier system of claim 1, wherein the at least one of the plurality of branch differential amplifying circuits includes: an impedance matching circuit and a power amplifying unit.

3. The power amplifier system of claim 2, wherein the impedance matching circuit includes an input impedance matching circuit disposed on an input signal side of the power amplifying unit.

4. The power amplifier system of claim 2, wherein the impedance matching circuit includes an output impedance matching circuit disposed on an output signal side of the power amplifying unit.

5. The power amplifier system of claim 4, wherein the output impedance matching circuit includes an impedance adjusting unit, the impedance adjusting unit being configured to adjust an output impedance of the power amplifying unit of at least one branch differential amplifying circuit other than a branch differential amplifying circuit where the output impedance matching circuit is located.

6. The power amplifier system of claim 5, wherein the impedance adjusting unit includes a switch, the switch being connected in parallel between a positive port and a negative port of a differential output port of the power amplifying unit on the branch differential amplifying circuit where the output impedance matching circuit is located.

7. The power amplifier system of claim 1, wherein at least two of the plurality of branch differential amplifying circuits start operating when an output power is greater than a first threshold value and start operating when the output power is greater than a second threshold value, respectively, and the second threshold value is greater than the first threshold value.

8. The power amplifier system of claim 7, wherein the operating state at which the output power is greater than the first threshold value is an operating state of a class A amplifier or an operating state of a class AB amplifier.

9. The power amplifier system of claim 7, wherein the operating state at which the output power is greater than the second threshold value is an operating state of a class B amplifier or a class C amplifier.

10. The power amplifier system of claim 5, wherein the differential synthesizer includes input ports of the plurality of sub-differential signals, an output port of the synthesized differential signal, and N pairs of differential coupling lines connected between the input ports of the plurality of sub-differential signals and the output port of the synthesized differential signal; a pair of a positive input port and a negative input port of at least one of the plurality of sub-differential signals is connected to a positive coupling line and a negative coupling line of different pairs of differential coupling lines in the N pairs of differential coupling lines, N≥2, and N is a positive integer.

11. The power amplifier system of claim 10, wherein the input ports of the plurality of sub-differential signals of the differential synthesizer are not isolated from each other.

12. The power amplifier system of claim 1, wherein the differential synthesizer includes input ports of the plurality of sub-differential signals, an output port of the synthesized differential signal, and N pairs of differential coupling lines connected between the input ports of the plurality of sub-differential signals and the output port of the synthesized differential signal; a pair of a positive input port and a negative input port of each of the plurality of sub-differential signals is connected to a positive coupling line and a negative coupling line of a corresponding pairs of differential coupling lines in the N pairs of differential coupling lines, N≥2, and N is a positive integer.

13. The power amplifier system of claim 12, wherein an isolation circuit is disposed between input ports of at least two sub-differential signals in the differential synthesizer.
